(19) United States
(12) Patent Application Publication
(10) Pub. No.: US 2011/0228014 A1
(43) Pub. Date: Sep. 22, 2011

(54) PIEZOELECTRIC ELEMENT, LIQUID EJECTING HEAD, AND LIQUID EJECTING APPARATUS

(75) Inventor: Toshiaki TAKAHASHI, Chino-shi (JP)

(73) Assignee: SEIKO EPSON CORPORATION, Tokyo (JP)

(21) Appl. No.: 13/048,207

(22) Filed: Mar. 15, 2011

(30) Foreign Application Priority Data
Mar. 16, 2010 (JP) 2010-058830

(51) Int. Cl. B41J 2/045; H01L 41/18

(52) U.S. Cl. 347/68; 310/311

(57) ABSTRACT

A piezoelectric element comprises electrodes and a piezoelectric member which is disposed between the electrodes. The piezoelectric member includes a first layer containing bismuth and titanium and a second layer containing bismuth lanthanum iron and manganese.

### CROSS-REFERENCE TO RELATED APPLICATIONS

This application claims the benefit of priority to Japanese Patent Application No. 2010-058830 filed Mar. 16, 2010, the contents of which are hereby incorporated by reference in their entirety.

### BACKGROUND

1. Technical Field

The present invention relates to a liquid ejecting head, a piezoelectric element and a piezoelectric actuator.

2. Related Art

A liquid ejecting head is incorporated in a liquid ejecting apparatus, such as an ink jet printer. In this instance, the liquid ejecting head is used for ejecting ink droplets to fly them, so that the ink jet printer can fix the ink on a medium such as paper and thus perform printing.

In general, a liquid ejecting head includes an actuator that applies a pressure to liquid to eject the liquid through a nozzle. Some of the actuators include, for example, a piezoelectric element. A type of the piezoelectric elements used in actuators has a structure in which a piezoelectric member made of a piezoelectric material capable of electromechanical conversion, such as a crystallized piezoelectric ceramic, is disposed between two electrodes. This type of piezoelectric element is deformed by receiving a voltage from the two electrodes. This deformation allows the actuator to operate in, for example, a deflection vibration mode.

It is preferable that piezoelectric materials used for this application have high piezoelectric characteristics, such as electromechanical conversion efficiency. Lead zirconate titanate (PZT) is superior in piezoelectric characteristics to other piezoelectric materials, and research and development have been conducted on PZT materials. On the other hand, as a desire grows to enhance the piezoelectric characteristics of the piezoelectric material, the demand for materials having low environmental load is increasingly rising. It is however difficult for PZT materials to meet the demand, and lead-free perovskite oxides have become developed as piezoelectric materials. JP-A-2008-069051 discloses BF-BKT ceramics having compositions expressed by a[BiFeO₃]-(1-x)[(Bi_{b}K_{1-b})TiO₃] (0.3≦a≦0.8, 0.4<b<0.6) as lead-free ceramics.

Bismuth titanate, which exhibits a larger displacement with electric field than other bismuth-based oxides and thus has high piezoelectric characteristics, is expected to replace PZT. However, a bismuth titanate film is often cracked in a process in which it is formed by a thin film forming method, or when it is deformed by applying an electric field to the film.

### SUMMARY

An advantage of some aspects of the invention is that it provides an actuator and a liquid ejecting head that include an environmentally friendly piezoelectric member unlikely to be cracked. Another advantage is that it provides a piezoelectric element including an environmentally friendly piezoelectric member unlikely to be cracked.

The following embodiments can solve at least part of the issues described above.

According to an aspect of the invention, a liquid ejecting head is provided which includes a piezoelectric actuator including a piezoelectric member and an electrode that applies a voltage to the piezoelectric member. The piezoelectric member includes at least one layer mainly containing bismuth titanate and at least one layer mainly containing bismuth lanthanum ferrate manganate.

The liquid ejecting head includes a piezoelectric member that can exhibit a large displacement and is unlikely to be cracked. Accordingly, the piezoelectric actuator exhibits a large displacement. Thus, the liquid ejecting head has high performance in ejecting liquid and high reliability.

The layer mainly containing bismuth lanthanum ferrate manganate may adjoin the electrode.

Such a piezoelectric member is preferentially oriented in the <100> direction. Consequently, the piezoelectric actuator has a large displacement, and the liquid ejecting head has high performance in ejecting liquid or the like.

The layer mainly containing bismuth lanthanum ferrate manganate may be disposed between the layers mainly containing bismuth titanate.

Such a piezoelectric member is more preferentially oriented in the <100> direction. Accordingly, the piezoelectric actuator has a large displacement, and the liquid ejecting head has high performance in ejecting liquid or the like.

The total thickness of the layer mainly containing bismuth titanate may be equal to or larger than the total thickness of the layer mainly containing bismuth lanthanum ferrate manganate.

Such a piezoelectric member is more preferentially oriented in the <100> direction. Accordingly, the piezoelectric actuator has a large displacement, and the liquid ejecting head has high performance in ejecting liquid or the like.

According to another aspect of the invention, a liquid ejecting apparatus is provided which includes the liquid ejecting head described above.

The liquid ejecting apparatus includes a liquid ejecting head including a piezoelectric member that can exhibit a large displacement and is unlikely to be cracked. Accordingly, the liquid ejecting apparatus exhibits high performance in ejecting liquid or the like and high reliability.

According to still another aspect of the invention, a piezoelectric element is provided which includes a piezoelectric member formed by a thin film forming method. The piezoelectric member includes a layer mainly containing bismuth titanate and a layer mainly containing bismuth lanthanum ferrate manganate, and an electrode that applies a voltage to the piezoelectric member.

The piezoelectric element includes a piezoelectric member that can exhibit a large displacement and is unlikely to be cracked. Accordingly, when the piezoelectric element is used as a piezoelectric actuator, the displacement of the piezoelectric actuator becomes large, and the liability can be enhanced.

### BRIEF DESCRIPTION OF THE DRAWINGS

The invention will be described with reference to the accompanying drawings, wherein like numbers reference like elements.

FIG. 1 is a schematic sectional view of a piezoelectric actuator or a piezoelectric element according to an embodiment of the invention.

FIG. 2 is a schematic sectional view of a liquid ejecting head according to an embodiment of the invention.

FIG. 3 is a schematic exploded perspective view of the liquid ejecting head.

FIG. 4 is a schematic perspective of a liquid ejecting apparatus according to an embodiment of the invention.

FIG. 5 is a representation of the results of surface observation of experimental examples, referential examples and comparative examples through a metallurgical microscope.

FIG. 6 is a representation of the results of surface observation of experimental examples, referential examples and comparative examples through a metallurgical microscope.

FIG. 7 is a representation of the X-ray diffraction patterns of piezoelectric elements of experimental examples, referential examples and comparative examples.

FIG. 8 is a representation of the X-ray diffraction patterns of piezoelectric elements of experimental examples, referential examples and comparative examples.

FIG. 9 is a representation of the X-ray diffraction patterns of piezoelectric elements of experimental examples, referential examples and comparative examples.

### DESCRIPTION OF EXEMPLARY EMBODIMENTS

Preferred embodiments of the invention will now be described with reference to the drawings. In the following description, some of the possible embodiments will be illustrated below. The invention is not limited to the embodiments disclosed below, and various modifications may be made within the scope and spirit of the invention. Also, all the components disclosed in the following embodiments are not required for the invention.

### 1. PIEZOELECTRIC ELEMENT AND PIEZOELECTRIC ACTUATOR

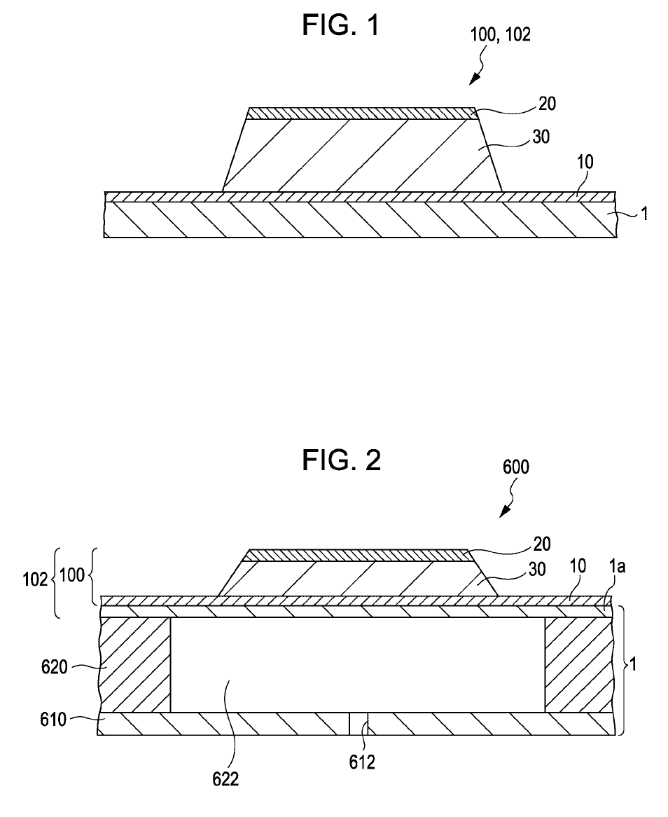

FIG. 1 is a sectional view of a piezoelectric element 100 according to an embodiment of the invention.

The piezoelectric element 100 includes a first electroconductive layer 10, a second electroconductive layer 20 and a piezoelectric member 30.

### 1.1. FIRST ELECTROCONDUCTIVE LAYER

The first electroconductive layer 10 is formed, for example, over a substrate 1. The substrate 1 may be a flat plate made of an electrical conductor, a semiconductor or an insulating material. The substrate 1 may be composed of a single layer or a plurality of layers. The substrate 1 may have any internal structure and may be a hollow plate, as long as the upper surface is flat. If a pressure chamber or the like is disposed under the substrate 1, like a liquid ejecting head that will be described later, the substrate 1 and the structure underlying the substrate 1 may be considered to be a substrate as a whole. The first electroconductive layer 10 and the substrate 1 may be separated by an additional layer, such as a layer enhancing the adhesion between the first electroconductive layer 10 and the substrate 1 or a layer enhancing the strength or the conductivity. Such a layer may be made of, for example, a metal, such as titanium, nickel or iridium, or an oxide of these metals.

The shape of the first electroconductive layer 10 is not particularly limited as long as it can oppose the second electroconductive layer 20. If the piezoelectric member 30 is a thin film as in the present embodiment, the first electroconductive layer 10 is preferably a thin film. For example, the first electroconductive layer 10 may have a thickness of 50 to 300 nm. The shape in plan view of the first electroconductive layer 10 is not also particularly limited as long as the piezoelectric member 30 can be disposed between the first electroconductive layer 10 and the second electroconductive layer 20. For example, the piezoelectric member 30 may be, for example, rectangular or round.

One of the functions of the first electroconductive layer 10 is to pair with the second electroconductive layer 20 so as to act as one of the electrodes that apply a voltage to the piezoelectric member 30 (for example, a lower electrode disposed under the piezoelectric member 30).

The first electroconductive layer 10 may be formed by sputtering (including DC sputtering, ion sputtering, and magnetron sputtering), vapor deposition, or MOCVD (Metal-Organic Chemical Vapor Deposition).

The substrate 1 may be a flexible vibration plate that can be deformed (bent) by the behavior of the piezoelectric member 30. In this instance, the piezoelectric element 100 acts as a piezoelectric actuator 102 including the vibration plate, the first electroconductive layer 10, the piezoelectric member 30 and the second electroconductive layer 20. That the substrate 1 is a flexible vibration plate means that the substrate 1 can bend. When a vibration plate is used as the substrate 1 and the piezoelectric actuator 102 is used in a liquid ejecting head, it is good enough that the substrate 1 can be bent to the extent that the capacity of the pressure chamber is varied to the same degree as the volume of the liquid is varied.

The substrate 1 acting as the vibration plate can be made of an inorganic oxide, such as zirconium oxide (ZrO₂), silicon nitride or silicon oxide, or an alloy, such as stainless steel. Among these materials, zirconium oxide is particularly preferable from the viewpoint of chemical stability and stiffness. In this instance as well, the substrate 1 may be composed of at least two layers made of those materials.

In the present embodiment, a vibration plate made of zirconium oxide is used as the substrate 1. Hence, the piezoelectric element 100 is substantially the same as a piezoelectric actuator 102 including a flexible vibration plate that can be deformed (bent) by the behavior of the piezoelectric member 30. In the following description, the piezoelectric element 100 and the piezoelectric actuator 102 can be compatible with each other.

### 1.2. SECOND ELECTROCONDUCTIVE LAYER

The second electroconductive layer 20 opposes the first electroconductive layer 10. The entirety or part of the second electroconductive layer 20 may oppose the first electroconductive layer 10. The shape of the second electroconductive layer 20 is not particularly limited as long as it can oppose the first electroconductive layer 10. If the piezoelectric member 30 is a thin film as in the present embodiment, the second electroconductive layer 20 is preferably a thin film. For example, the second electroconductive layer 20 has a thickness of 50 to 300 nm. The shape in plan view of the second electroconductive layer 20 is not also particularly limited as long as the piezoelectric member 30 can be disposed between the first electroconductive layer 10 and the second electroconductive layer 10. For example, it may be, for example, rectangular or round.

One of the functions of the second electroconductive layer 20 is to act as one of the electrodes that apply a voltage to the piezoelectric member (for example, an upper electrode disposed over the piezoelectric member 30). The second electroconductive layer 20 may be made of a metal, such as nickel, iridium or platinum, a conductive oxide of these metals, such as iridium oxide, complex oxide of strontium and ruthenium (SrRuOx:SRO), or complex oxide of lanthanum and nickel (LaNiOx:LNG). The second electroconductive layer 20 may be composed of a single layer or a plurality of layers made of different materials.

Although, in FIG. 1, the first electroconductive layer 10 has a larger area than the second electroconductive layer 20, the second electroconductive layer 20 may have a larger area than the first electroconductive layer 10. Such a second electroconductive layer 20 may extend to the side surfaces of the piezoelectric member 30, and can function to protect the piezoelectric member 30 from moisture, hydrogen or the like.

### 1.3. PIEZOELECTRIC MEMBER

The piezoelectric member 30 is disposed between the first electroconductive layer 10 and the second electroconductive layer 20. The piezoelectric member 30 may be in contact with at least one of the first electroconductive layer 10 and the second electroconductive layer 20. In the embodiment shown in FIG. 1, the piezoelectric member 30 is in contact with both the first electroconductive layer 20 and the second electroconductive layer 20.

The piezoelectric member 30 can be formed by a thin film forming method. The thin film forming method used herein refers to at least one method selected from the group consisting of sputtering, vapor deposition, MOCVD, MOD (Metal-Organic Decomposition), PLD (Pulsed Laser Deposition) (laser ablation method), mist deposition, spin coating, and a sol-gel method. This means that the piezoelectric member 30 of the present embodiment is not formed in a bulk state, or it is not formed by, for example, grinding a bulk piezoelectric layer to reduce the thickness.

The thickness of the piezoelectric member 30 is not particularly limited as long as it is formed by a thin film forming method, and may be in the range of 100 to 3000 nm. For forming a thick piezoelectric member 30 by a thin film forming method, the piezoelectric member 30 may be formed by long-time deposition of the material, such as sputtering, vapor deposition or MOCVD, or coating such as MOD or a sol-gel method and firing may be repeated. If a multilayer piezoelectric member is formed, the layers of the multilayer structure may be formed by different thin film forming methods.

The piezoelectric member 30 of the present embodiment has a structure including a layer mainly containing bismuth titanate and a layer mainly containing bismuth lanthanum ferrate manganate. In the description hereinafter, the layer mainly containing bismuth titanate may be referred to as the BT layer, and the layer mainly containing bismuth lanthanum ferrate manganate may be referred to as the BLFM layer.

### 1.3.1. LAYER MAINLY CONTAINING BISMUTH TITANATE (BT LAYER)

The BT layer mainly contains bismuth titanate. The words “mainly contains bismuth titanate” mean that the layer may contain 20 at % or less of elements other than titanium, oxygen and bismuth, and that a trace amount of elements other than titanium, oxygen, and bismuth may or may not be detected by an analysis.

The piezoelectric member 30 includes at least one BT layer.

Bismuth titanate is a complex oxide expressed by BiTiO₃ (hereinafter may be represented by BT), and can be expressed by a general formula:

BiₓTi₍₁₋ₓ₎O₃ (I).

BT is an ABO₃ type complex oxide, that is, a so-called perovskite oxide, and can have a perovskite crystal structure by being crystallized. BT having a perovskite crystal structure can exhibit piezoelectric characteristics. Thus, the piezoelectric member 30 can be deformed by applying a voltage from the first electroconductive layer 10 and the second electroconductive layer 20 (electromechanical conversion). The deformation of the piezoelectric member 30, for example, bends or vibrates the substrate 1, and thus a piezoelectric actuator 102 is defined.

In the composition of the BT layer of the piezoelectric member 30 expressed by the above formula (I), x can be more than 0 and less than 1. x May be a value obtained from the amounts of the raw materials, or from the composition of the BT layer.

The BT layer may have a thickness in the range of 20 to 150 nm.

One of the functions of the BT layer is particularly to increase the displacement of the piezoelectric element 100 when an electric field has been applied to the piezoelectric member 30. Since the piezoelectric element 100 of the present embodiment has the piezoelectric member 30 including the BT layer, a large displacement can be produced.

### 1.3.2. LAYER MAINLY CONTAINING BISMUTH LANTHANUM FERRATE MANGANATE (BLFM LAYER)

The piezoelectric member 30 includes at least one BLFM layer.

The BLFM layer mainly contains bismuth lanthanum ferrate manganate. The words “mainly contains bismuth lanthanum ferrate manganate” mean that the layer may contain 20 at % or less of elements other than iron, manganese, bismuth, lanthanum titanium and oxygen, and that a trace amount of elements other than iron, manganese, bismuth, lanthanum and oxygen may or may not be detected by an analysis.

Bismuth lanthanum ferrate manganate is a complex oxide expressed by (Bi,La)(Fe,Mn)O₃ (hereinafter may be represented by BLFM), and can be expressed by a general formula:

(Bi_{(1-y)}La_{y})(Fe_{(1-z)}Mn_{z})O₃ (II).

BLFM is an ABO₃ type complex oxide, that is, a so-called perovskite oxide, and can have a perovskite crystal structure by being crystallized. BLFM having a perovskite crystal structure can exhibit piezoelectric characteristics. Thus, the piezoelectric member 30 can be deformed by applying a voltage from the first electroconductive layer 10 and the second electroconductive layer 20 (electromechanical conversion). The deformation of the piezoelectric member 30, for example, bends or vibrates the substrate 1, and thus a piezoelectric actuator 102 is defined.

In the composition of the BLFM used in the present embodiment, expressed by the above formula (II), y and z can each be in the range of 0 to 1. y And z may be values obtained from the raw materials or from the composition of the BLFM layer.

The BLFM layer may have a thickness in the range of 20 to 150 nm.

One of the functions of the BLFM layer is to reduce the risk of cracks in the piezoelectric member 30. As described above, the BT layer can exhibit large displacement, but can crack (destruction) if it is used as the piezoelectric member 30. The BT layer by itself is liable to crack in a manufacturing process (during firing) or when a voltage is applied to deform the BT layer. In the piezoelectric member 30 of the present embodiment, the BLFM layer formed on the BT layer can reduce the internal stress in the piezoelectric member 30 to reduce the risk of cracks in the piezoelectric member 30.

Another function of the BLFM layer is to control the crystal orientation of the BT layer. While the BT layer tends to be randomly oriented when it is crystallized, the BLFM layer is likely to be preferentially oriented in the <100> direction. By forming the BT layer and the BLFM layer together, both layers can be preferentially oriented in the <100> direction. Accordingly, by forming a BT layer and a BLFM layer one on top of the other to form a piezoelectric member 30, a large displacement of the BT layer can be further increased.

### 1.3.3. MULTILAYER STRUCTURE INCLUDING BLFM LAYER AND BT LAYER

The multilayer structure of the piezoelectric member 30 including the BLFM layer and the BT layer is not particularly limited in number of layers, order of layers and so forth, and BLFM layers and BT layers can be formed repeatedly until the piezoelectric member 30 has a desired thickness. The BLFM layer tends to be preferentially oriented in the <100> directions and can preferentially align the crystals of the BT layer in the <100> directions. Accordingly, by appropriately selecting the multilayer structure, a superior piezoelectric member 30 and piezoelectric element 100 can be provided.

In the embodiments of the invention, preferred orientation or preferentially orienting means that when the material of a layer has a polycrystalline structure, the axes of a large proportion of microcrystals of the layer extend in the direction of the normal to the surface of the layer. Hence, in the description herein, for example, “<100> preferred orientation” or “preferentially orienting in the <100> direction” means that there are a large proportion of microcrystals whose axes in the [100] direction extend along the normal to the surface of the layer.

When a piezoelectric ceramic layer is formed by a thin layer forming method, the ceramic layer often takes a perovskite crystal structure by crystallization. This is because that a piezoelectric element of perovskite crystals preferentially oriented in the <100> direction exhibits large displacement. For example, in order to aligning the PZT crystals of a PZT piezoelectric member preferentially in the <100> direction, the material, orientation and surface properties of the electrodes are often modified so that the PZT crystals can be spontaneously oriented preferentially in the <100> direction.

The piezoelectric member 30 of the present embodiment has a multilayer structure including a BT layer and a BLFM layer. The BLFM layer tends to be spontaneously oriented preferentially in the <100> direction, but the BT layer does not. Accordingly, by forming a BLFM layer on a BT layer, the BLFM layer allows the BT layer to be preferentially oriented in the <100> direction.

Consequently, in the piezoelectric element 100 of the present embodiment, the piezoelectric member 30 does not crack easily, and the piezoelectric characteristics, such as displacement, can be enhanced.

In a multilayer structure of the piezoelectric member 30, the BLFM layer may be formed so as to adjoin the electrodes. More specifically, a BLFM layer may be formed on the first electroconductive layer 10, and subsequently at least one BT layer and then at least one BLFM layer are formed on the BLFM layer so that the uppermost layer is defined by a BLFM layer. The second electroconductive layer 20 is formed on the uppermost BLFM layer. This structure makes it difficult to crack the piezoelectric member 30 and allows the piezoelectric member 30 to be oriented preferentially in the <100> directions, and thus the displacement can be increased.

In another multilayer structure of the piezoelectric member 30, a BLFM layer may be disposed between BT layers. This structure makes it difficult to crack the piezoelectric member 30 and increases the displacement of the piezoelectric element 100.

Alternatively, the BT layers may be formed so that their total thickness becomes equal to or larger than the total thickness of the BLFM layers. This structure can produce both the effect of the BT layer to increase the displacement and the effect of the BLFM layer to reduce the occurrence of cracks.

In still another multilayer structure of the piezoelectric member 30, at least one BT layer is disposed between a pair of BLFM layers. In this instance, the distance between the pair of the BLFM layers may be 250 nm or less. Also, the BT layer between the pair of the BLFM layers may have a thickness of 250 nm or less. This structure can enhance the action of the BLFM layers on the crystal orientation of the BT layer, and accordingly, the displacement of the BT layer can be further increased.

The above-described multilayer structures of the piezoelectric member 30 may be combined.

### 1.4. ADVANTAGES

As described above, the piezoelectric member 30 of the present embodiment is unlikely to be crack and can produce a largely displacement. That is, the piezoelectric member 30, which has a multilayer structure including the BT layer and the BLFM layer, has both the functions of the BT layer to increase the displacement and the function of the BLFM layer to reduce the risk of cracks in the BT layer. Consequently, the piezoelectric member 30 can efficiently bend or vibrate the substrate 1 by applying an electric field from the first electroconductive layer 10 and the second electroconductive layer 20. Thus, the piezoelectric element 100 is unlikely to break and has high reliability.

Since the piezoelectric element 100 (piezoelectric actuator 102) of the present embodiment includes the above-described piezoelectric member 30, it is features of the piezoelectric element 100 that at least the piezoelectric member 30 is unlikely to be cracked and has high reliability, and that the displacement is large.

The piezoelectric element 100 of the present embodiment can be used in a wide range of applications. For example, the piezoelectric actuator 102 can be used in liquid ejecting apparatuses, such as liquid ejecting heads and ink jet printers, and the piezoelectric element 100 can be used in various sensors such as gyro sensors and acceleration sensors, timing devices such as fork oscillators, and ultrasonic devices such as ultrasonic motors.

### 2. METHOD FOR MANUFACTURING PIEZOELECTRIC ELEMENT

The piezoelectric element 100 can be manufactured by the following method.

First, a substrate 1 is prepared, and a first electroconductive layer 10 is formed on the substrate 1. The first electroconductive layer 20 may be formed by, for example, sputtering, plating, or vacuum vapor deposition. The first electroconductive layer 10 may be patterned if necessary.

Then, a piezoelectric member 30 is formed on the first electroconductive layer 10. The piezoelectric member 30 may be formed by, for example, at least one method selected from the group consisting of sputtering, vapor deposition, MOCVD, MOD, PLD (laser ablation method), mist deposition, spin coating and a sol-gel method, or a combination of these methods, as described above. The piezoelectric member 30 can be crystallized, for example, at a temperature in the range of 500 to 800° C. in an atmosphere of at least one of oxygen and nitrogen. Thus the piezoelectric member 30 can be crystallized. This crystallization may be performed after patterning the piezoelectric member 30. The above operations may be repeated as required until the piezoelectric member 30 has a desired thickness.

If the piezoelectric member 30 is formed by a chemical solution method such as a sol-gel method or MOD, precursor solutions having elemental compositions of the BLFM layer and the BT layer are applied by, for example, spin coating, and then the coatings of the precursor solutions are fired. Such a precursor solution may be prepared by mixing metal compounds as cited below with a solvent, such as n-butanol.

Metal compounds containing Bi include triethoxy bismuth, tri-i-propoxy bismuth, bismuth acetylacetonate, bismuth nitrate, bismuth acetate, bismuth citrate, bismuth oxalate, bismuth tartaric, and bismuth 2-ethylhexanoate.

Metal compounds containing Fe include triethoxy iron, tri-i-propoxy iron, tris(acetylacetonate)iron, iron nitrate, iron acetate, iron oxalate, iron tartarate, iron citrate, and iron 2-ethylhexanoate.

Metal compounds containing Ti include tetramethoxy titanium, tetraethoxy titanium, tetra-i-propoxy titanium, tetra-n-propoxy titanium, tetra-i-butoxy titanium, tetra-n-butoxy titanium, tetra-t-butoxy titanium, titanium acetylacetonate, titanium nitrate, titanium acetate, titanium oxalate, titanium tartarate, titanium citrate, and tetra(2-ethylhexyl) titanate.

Metal compounds containing La include lanthanum 2-ethylhexanoate.

Metal compound containing Mn include di-i-propoxy manganese, manganese (III) acetylacetonate, manganese nitrate, manganese acetate, manganese citrate, manganese oxalate, manganese tartarate, and manganese 2-ethylhexanoate.

Subsequently, a second electroconductive layer 20 is formed on the piezoelectric member 30. The second electroconductive layer 20 may be formed by, for example, sputtering, plating, or vacuum vapor deposition. The second electroconductive layer 20 and the piezoelectric member 30 are patterned into a desired shape to complete a piezoelectric element. The second electroconductive layer 20 and the piezoelectric member 30 may be simultaneously patterned, if necessary. Through the above operations, the piezoelectric element 100 of the present embodiment can be manufactured.

### 3. LIQUID EJECTING HEAD

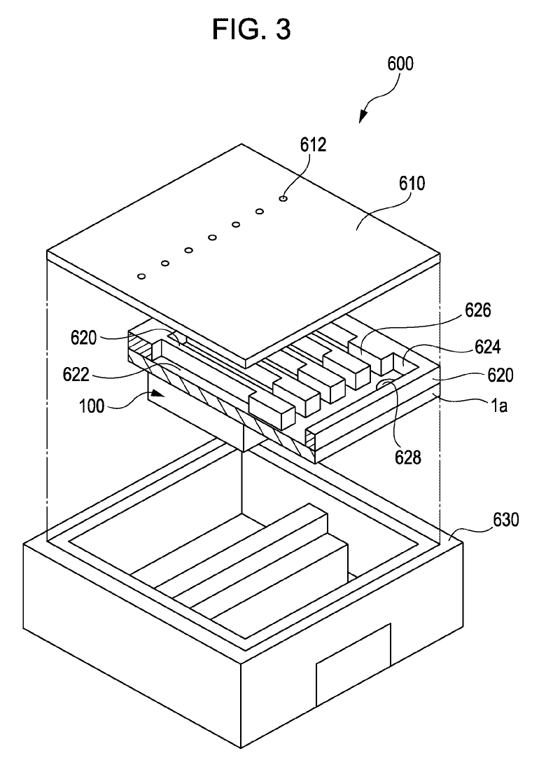

A liquid ejecting head 600 will now be described as one of the applications of the piezoelectric element (piezoelectric actuator) of the present embodiment, with reference to drawings. FIG. 2 is a schematic sectional view of a liquid ejecting head 600. FIG. 3 is an exploded perspective view of the liquid ejecting head 600, showing a state where the head is reversed from the normal position.

The liquid ejecting head 600 may include the piezoelectric element (piezoelectric actuator). In the liquid ejecting head 600 described below, a piezoelectric element 100 is disposed on a substrate 1 including a vibration plate 1a, and the piezoelectric element 100 and the vibration plate 1a define a piezoelectric actuator 102.

The liquid ejecting head 600 includes a nozzle plate 610 having nozzle apertures 612, a pressure chamber substrate 620 having pressure chambers 622 therein, and the piezoelectric element 100, as shown in FIGS. 2 and 3. In addition, the liquid ejecting head 600 may include an enclosure 630, as shown in FIG. 3. The piezoelectric element 100 shown in FIG. 3 is simplified.

The nozzle plate 610 has nozzle apertures 612, as shown in FIGS. 2 and 3. Ink is ejected through the nozzle apertures 612. The nozzle apertures 612 may be aligned in a line. The nozzle plate 610 may be made of silicon or stainless steel (SUS).

The pressure chamber substrate 620 is disposed on the nozzle plate 610 (under the nozzle plate in FIG. 3). The pressure chamber substrate 620 may be made of, for example, silicon. The pressure chamber substrate 620 divides a space between the nozzle plate 610 and the vibration plate 1a so as to form a reservoir (liquid storage portion) 624, delivering paths 626 communicating with the reservoir 624, and pressure chambers 622 communicating with the respective delivering paths 626, as shown in FIG. 3. In the present embodiment, the reservoir 624, the delivering paths 626 and the pressure chambers 622 are described separately. However, they function as a liquid flow channel, and the flow channel can be arbitrarily designed without particular limitation. The delivering paths 626 shown in FIG. 3 are each partially narrowed, but can be formed in any shape according to the design without being limited to such a shape. The reservoir 624, the delivering paths 626 and the pressure chambers 622 are partitioned by the nozzle plate 610, the pressure chamber substrate 620 and the vibration plate 1a. The reservoir 624 can temporally store ink supplied from the outside (for example, an ink cartridge) through a through hole 628 formed in the vibration plate 1a. The ink in the reservoir 624 is delivered to the pressure chambers 622 through the delivering paths 626. The capacity of the pressure chamber 622 is varied by the deformation of the vibration plate 1a. The pressure chamber 622 communicates with the nozzle aperture 612. By varying the capacity of the pressure chamber 622, the ink is ejected through the nozzle aperture 612.

The piezoelectric element 100 is disposed over the pressure chamber substrate 620 (under the pressure chamber substrate in FIG. 3). The piezoelectric element 100 is electrically connected to a piezoelectric element driving circuit (not shown) so as to be operated (for vibration or deformation) according to the signal from the piezoelectric element driving circuit. The vibration plate 1a is deformed by the behavior of the piezoelectric member 30 to vary the pressure in the pressure chamber 622 as required.

The enclosure 630 accommodates the nozzle plate 610, the pressure chamber substrate 620 and the piezoelectric element 100, as shown in FIG. 3. The enclosure 630 can be made of, for example, a resin or a metal.

The liquid ejecting head 600 includes the piezoelectric element 100 that is superior at least in withstand voltage. Accordingly, the liquid ejecting head 600 has a high withstand voltage and can operate at higher voltages than known liquid ejecting heads; hence, the liquid ejecting head 100 exhibits high performance in ejecting liquid or the like.

In the above description, an ink jet recording head have been illustrated as an embodiment of the liquid ejecting head 600. However, the liquid ejecting head may be used as a color material ejecting head used for manufacturing color filters of, for example, liquid crystal display, an electrode material ejecting head used for forming electrodes of an organic EL display or a field emission display (FED), or a bioorganic material ejecting head used for manufacturing bio-chips.

### 4. LIQUID EJECTING APPARATUS

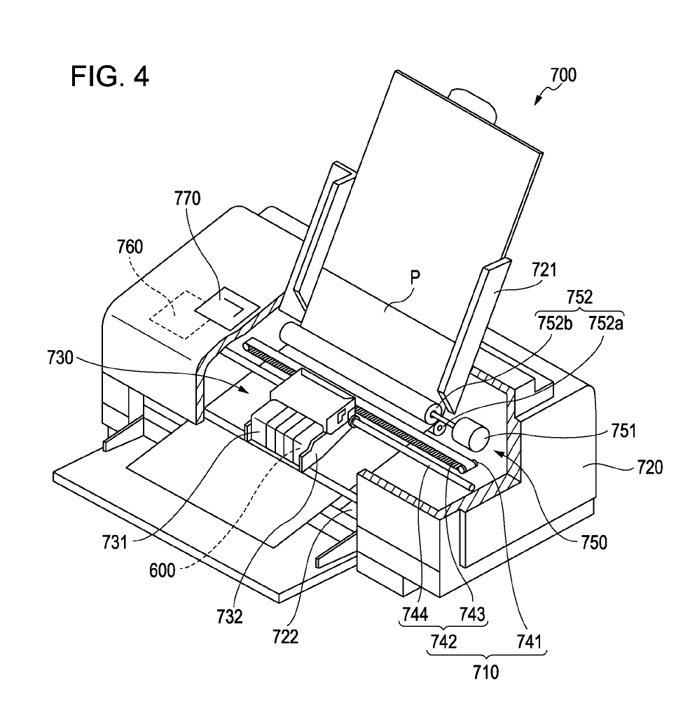

A liquid ejecting apparatus according to an embodiment of the invention will now be described with reference to drawings. The liquid ejecting apparatus includes the above-described liquid ejecting head. In the following description, the liquid ejecting apparatus functions as an ink jet printer including the liquid ejecting head. FIG. 4 is a schematic perspective view of the liquid ejecting apparatus 700 of the present embodiment.

The liquid ejecting apparatus 700 includes a head unit 730, a driving section 710, and a control section 760, as shown in FIG. 4. The liquid ejecting apparatus 700 further includes a apparatus body 720, a paper feeding section 750, a tray 721 on which recording paper P is placed, a paper ejecting port 722 from which the recording paper P is ejected, and a control panel 770 disposed on the upper surface of the apparatus body 720.

The head unit 730 includes an ink jet recording head (hereinafter may be simply referred to as the head) including the liquid ejecting head 600. The head unit 730 further includes an ink cartridge 731 delivering an ink to the head and a carrying portion (carriage) 732 on which the head and the ink cartridge 731 are disposed.

The driving section 710 reciprocally moves the head unit 730. The driving section 710 includes a carriage motor 741 acting as a driving source of the head unit 730, and a reciprocal movement mechanism 742 allowing the head unit 730 to be reciprocally moved by the rotation of the carriage motor 741.

The reciprocal movement mechanism 742 includes a carriage guide shaft 744 whose ends are held by a frame (not shown), and a timing belt 743 extending in parallel with the carriage guide shaft 744. The carriage guide shaft 744 supports the carriage 732 so as to allow the reciprocal movement of the carriage 732. The carriage 732 is secured to part of the timing belt 743. When the timing belt 743 is moved by the operation of the carriage motor 741, the head unit 730 reciprocally moves along the carriage guide shaft 744. The head ejects ink during the reciprocal movement to print on the recording paper P.

In the liquid ejecting apparatus of the present embodiment, printing is performed while both the liquid ejecting head 600 and the recording paper P are moving. However, only either the liquid ejecting head 600 or the recording paper P may move, as long as the liquid ejecting head 600 can perform recording on paper P while the positions of the head 600 and the recording paper P are relatively changed. In the present embodiment, printing is performed on the recording paper P. However, the recording medium on which the liquid ejecting apparatus performs printing is not limited to paper, and it can be appropriately selected from a wide range of media including cloth, plastic sheets, and metal sheets.

The control section 760 can control the head unit 730, the driving section 710 and the paper feeding section 750.

The paper feeding section 750 feeds recording paper P toward the head unit 730 from the tray 721. The paper feeding section 750 includes a paper feeding motor 751 acting as a driving source, and a paper feeding roller 752 rotated by the operation of the paper feeding motor 751. The paper feeding roller 752 includes a driven roller 752a and a driving roller 752b vertically opposing each other with the recording paper P therebetween. The driving roller 752b is coupled with the paper feeding motor 751. When the paper feeding section 750 is driven by the control section 760, the recording paper P is transported under the head unit 730.

The head unit 730, the driving section 710, the control section 760 and the paper feeding section 750 are disposed within the apparatus body 720.

The liquid ejecting apparatus 700 includes the liquid ejecting head 600 having a high withstand voltage. Accordingly, the liquid ejecting apparatus 700 exhibits high performance in ejecting liquid or the like.

Although the liquid ejecting apparatus 700 of the present embodiment includes a single liquid ejecting head 600 that can perform printing on a recording medium, the liquid ejecting head 600 may includes a plurality of liquid ejecting heads. If a plurality of liquid ejecting heads are used, they may be independently operated as described above, or may be connected to each other to define a single head. Such a head including a plurality of heads may be, for example, a line head.

In the above description, an ink jet printer has been described as an embodiment of the liquid ejecting apparatus 700 of the invention. The liquid ejecting apparatus can also be applied to industrial fields. In this instance, the liquid ejected from the apparatus may be a functional material whose viscosity has been adjusted with a solvent or disperse medium. The liquid ejecting apparatus of the embodiments of the invention can be used as color material ejecting apparatuses used for manufacturing color filters of liquid crystal displays, liquid material ejecting apparatuses used for forming electrodes and color filters of organic EL displays, field emission displays (FEDs) and electrophoretic displays, and bioorganic material ejecting apparatus used for manufacturing bio-chips, in addition to the above-described recording apparatus or printer.

### 5. EXPERIMENTAL EXAMPLES AND REFERENTIAL EXAMPLES

The present invention will be further described with reference to experimental examples, referential examples and comparative examples. However, the invention is not limited to the following Experimental Examples.

### 5.1. PREPARATION OF PIEZOELECTRIC MEMBER

Piezoelectric members of Experimental Examples 1 to 8, Referential Examples 1 and 2, and Comparative Examples 1 and 2 were formed as below.

For each example, the same substrate (including a platinum layer) was used. The substrate was made of monocrystalline silicon, and includes a silicon dioxide insulating film formed over the surface of the monocrystalline silicon by thermal oxidation, and a platinum layer formed on the insulating film by sputtering.

Each piezoelectric member of the Experimental Examples, Referential Examples and the Comparative Examples was obtained by forming BT layers and BLFM layers on the substrate by a chemical solution method.

The precursor solution for forming the BT layer was prepared by mixing bismuth 2-ethylhexanoate and tetraethoxy titanium with a solvent n-butanol. The precursor solution contained bismuth and titanium in a proportion according to the stoichiometrical composition.

The precursor solution for forming the BLFM layer was prepared by mixing bismuth 2-ethylhexanoate, lanthanum 2-ethylhexanoate, triethoxy iron and manganese 2-ethylhexanoate with a solvent n-butanol. The precursor solution contained each element in a proportion according to the stoichiometrical composition.

The BT layer and the BLFM layer were formed by spin coating. The coatings of the precursor solutions were subjected to drying, degreasing and crystallization as will be described below. Spin coating was performed first at a rotational speed of 500 rpm for 10 seconds, and then at 3000 rpm for 30 seconds.

The coating of each precursor solution was dried at 150 to 200° C. for 2 minutes in the air. Subsequently, in the air, the precursor coating was heat-treated at 400° C. for 4 minute to remove organic components from the precursor coating (degreasing). The thicknesses of the BT layer and the BLFM layer formed by each series of the above operations were 80 nm.

In Experimental Examples 1 and 2 and Referential Example 1, when a BLFM layer had been formed as the first layer of the piezoelectric member on the substrate, the specimen was fired in a nitrogen flow with a flow rate of 0.5 L/min in a firing furnace (Rapid Thermal Annealing (RTA) furnace) at temperatures from 600° C. to 800° C. for 3 minutes.

In Experimental Examples 3 and 4 and Comparative Example 1, when the BT layer had been formed as the first layer of the piezoelectric member on the substrate, the specimen was fired in a nitrogen flow with a flow rate of 0.5 L/min in a firing furnace (RTA furnace) at temperatures from 600° C. to 800° C. for 2 minutes.

In Experimental Examples 1 to 4, Referential Example 1 and Comparative Example 1, seven BT and BLFM layers in total were formed. In each case, when the fourth layer had been formed and when the seventh layer had been formed, the specimen was fired in a nitrogen flow with a flow rate of 0.5 L/m in a firing furnace (RTA furnace) at temperatures from 600° C. to 800° C. The fourth layer was fired for 3 minutes and the seventh layer was fired for 5 minutes.

In Experimental Examples 5 and 6 and Referential Example 2, when first two BLFM layers had been formed, the specimen was fired in a nitrogen flow with a flow rate of 0.5 L/m in a firing furnace (RTA furnace) at temperatures from 600° C. to 800° C. for 3 minutes.

In Experimental Examples 7 and 8 and Comparative Example 2, when first two BT layers had been formed, the specimen was fired in a nitrogen flow with a flow rate of 0.5 L/min in a firing furnace (RTA furnace) at temperatures from 600° C. to 800° C. for 2 minutes.

In Experimental Examples 5 to 8, Referential Example 2 and Comparative Example 2, eight BT and BLFM layers in total were formed. In each case, when the fifth layer has been formed and when the eighth layer had been formed, the specimen was fired in a nitrogen flow with a flow rate of 0.5 L/m in a firing furnace (RTA furnace) at temperatures from 600° C. to 800° C. The fifth layer was fired for 3 minutes and the eighth layer was fired for 5 minutes.

Piezoelectric members of Experimental Examples 9 to 11 were formed as below.

In Experimental Examples 9 and 10, two or three BT layers were formed on a BLFM layer. In either case, when the third layer or the fourth layer had been formed, the spacemen was fired in an oxygen flow in a firing furnace (RTA furnace) at temperatures from 600° C. to 800° C. for 3 minutes.

In Experimental Example 11, two BT layers were formed on a BLFM layer, and when the first layer (BLFM layer) has been formed, the spacemen was fired in an oxygen flow in a firing furnace (RTA furnace) at temperatures from 600° C. to 800° C. for 3 minutes.

In Referential Example 3 and Comparative Example 3, three BLFM layers or three BT layers were continuously formed. When the third layer had been formed, the spacemen was fired in an oxygen flow in a firing furnace (RTA furnace) at temperatures from 600° C. to 800° C. for 3 minutes.

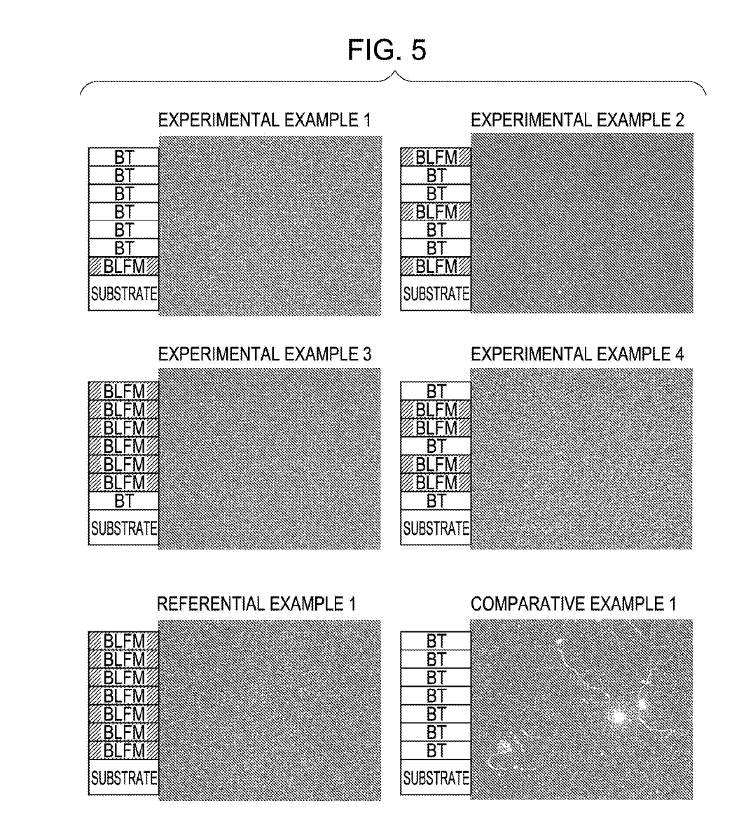

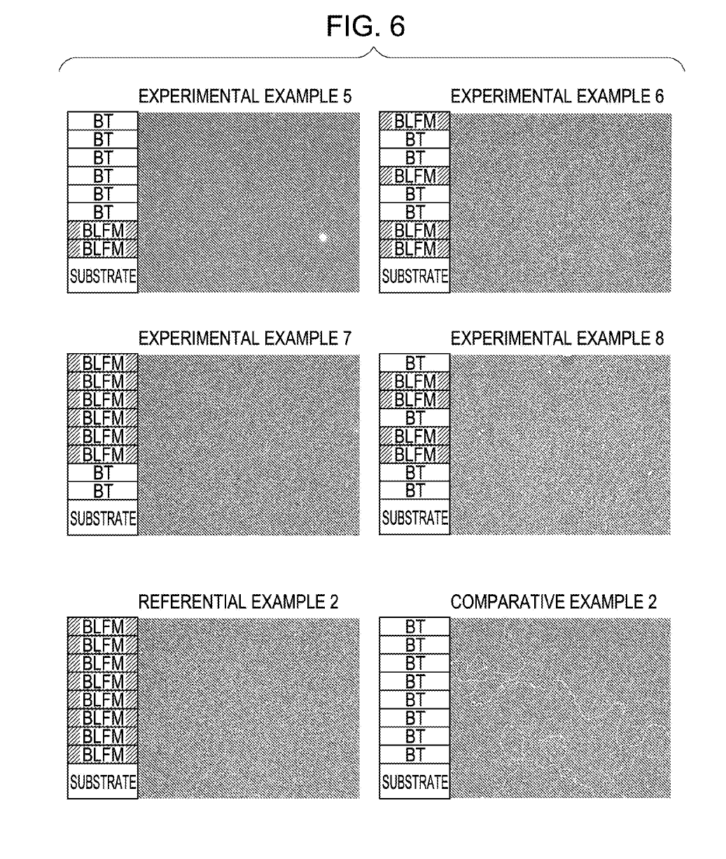

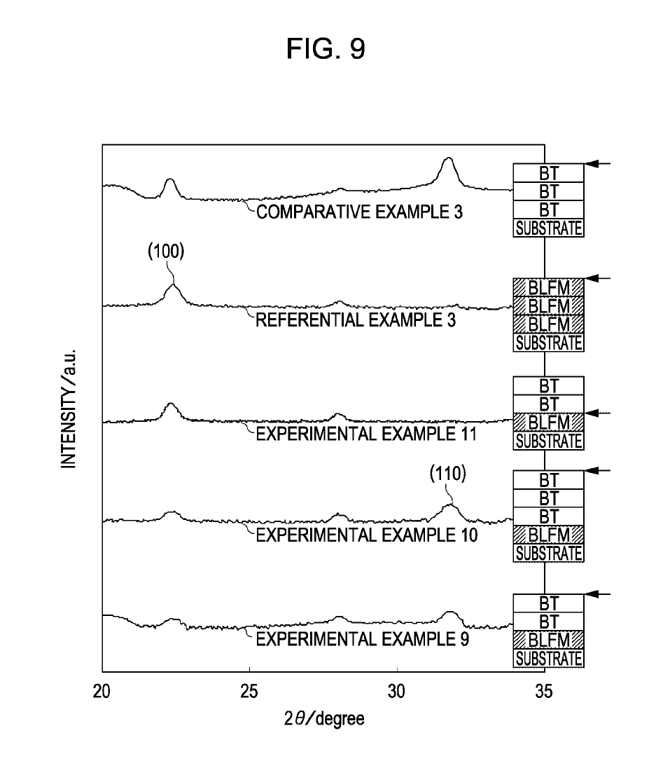

FIGS. 5 and 6 show the schematic multilayer structures of Experimental Examples 1 to 8, Referential Examples 1 and 2, and Comparative Examples 1 and 2. FIG. 9 is a schematic representation showing the multilayer structures and the firing positions of the multilayer structures of Experimental Examples 9 to 11, Referential Example 3 and Comparative Example 3.

### 5.2. EVALUATIONS OF PIEZOELECTRIC MEMBERS

### 5.2.1. OBSERVATION THROUGH METALLURGICAL MICROSCOPE

Each piezoelectric member was observed through a metallurgical microscope.

### 5.2.2. X-RAY DIFFRACTION (XRD)

Each piezoelectric member not subjected to patterning of Experimental Examples, Referential Examples and Comparative Examples was measured for the X-ray diffraction (XRD) pattern with D8 Discover (manufactured by Bruker AXS) at room temperature, using Cu—Ka radiation.

### 5.3. EVALUATION RESULTS

FIG. 5 shows the results of surface observation of the piezoelectric members of Experimental Examples 1 to 4, Referential Example 1 and Comparative Example 1. FIG. 6 shows the results of surface observation of the piezoelectric members of Experimental Examples 5 to 8, Referential Example 2 and Comparative Example 2.

As is clear from FIGS. 5 and 6, the piezoelectric members of Experimental Examples and Referential Examples, each of which has a multilayer structure including at least one BLFM layer, were fired without being cracked. On the other hand, in the piezoelectric members of the Comparative Examples, each of which have a multilayer structure composed of BT layers, white lies were observed in the results. This shows that cracks occurred in the piezoelectric member.

These results show that piezoelectric members including BT layers and at least one BLFM layer do not easily crack as with a piezoelectric member composed of BLFM layers.

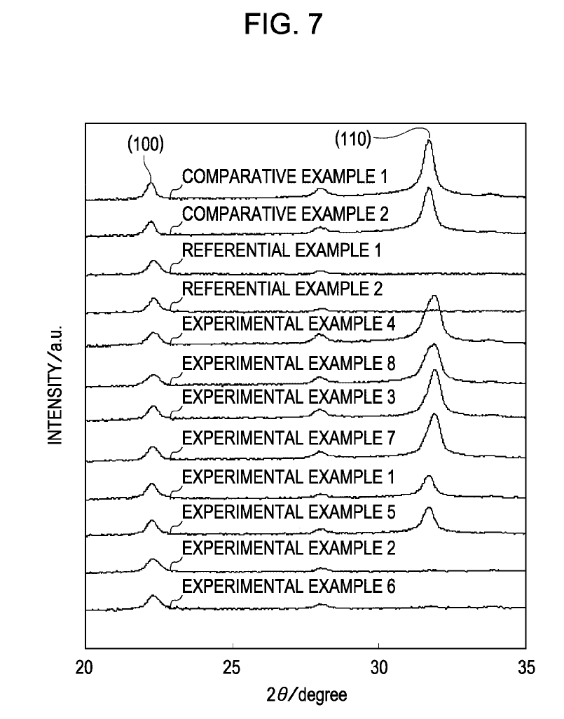

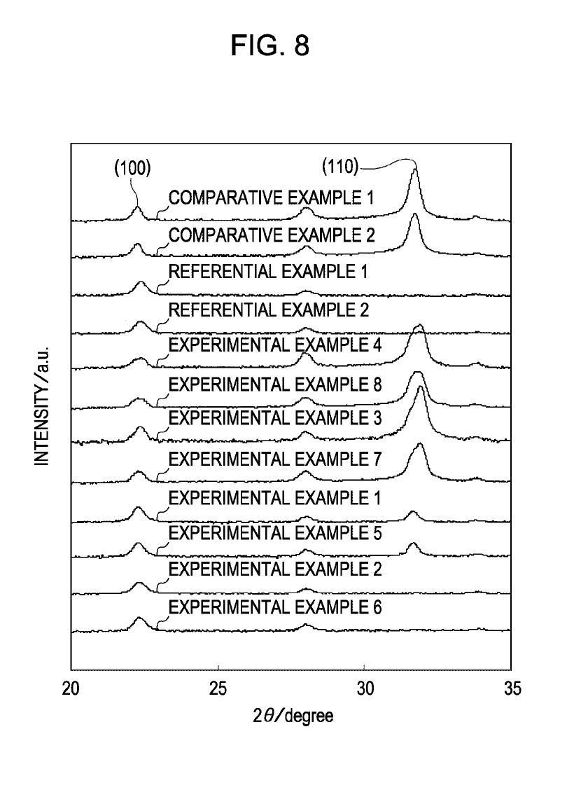

FIG. 7 shows XRD patterns of the piezoelectric members of Experimental Examples 1 to 8, Referential Example 1 and 2, and Comparative Examples 1 and 2. In FIG. 7, the XRD patterns of Experimental Examples 1 to 4, Referential Example 1 and Comparative Example 1 were each measured in a state where seven BT and BLFM layers in total had been formed, and the XRD patterns of Experimental Examples 5 to 8, Referential Example 2 and Comparative Example 2 were each measured in a state where eight BT and BLFM layers in total had been formed. FIG. 8 shows XRD patterns of the piezoelectric members of Experimental Examples 1 to 8, Referential Example 1 and 2, and Comparative Examples 1 and 2. In FIG. 8, the XRD patterns of Experimental Examples 1 to 4, Referential Example 1 and Comparative Example 1 were each measured in a state where four BT and BLFM layers in total had been formed, and the XRD patterns of Experimental Examples 5 to 8, Referential Example 2 and Comparative Example 2 were each measured in a state where five BT and BLFM layers in total had been formed.

FIGS. 7 and 8 show that the XRD patterns of the piezoelectric members of Experimental Examples 2 and 6 and Referential Examples 1 and 2 do not have a peak representing the (110) plane of the perovskite crystal structure. Consequently, it has been found that these piezoelectric members are favorably oriented preferentially in the <100> direction. On the other hand, the piezoelectric members of Comparative Examples 1 and 2, which do not include a BLFM layer, have a risk of cracks and a random crystal orientation.

In Experimental Examples 1 and 5, the peak representing the (110) plane in a state shown in FIG. 8 where the piezoelectric member has fewer layers (four layers in total in Experimental Example 1, five layers in total in Experimental Example 5) than the completed state decreases from the peak in a state where the piezoelectric member has more layers (seven layers in total in Experimental Example 1, eight layers in total in Experimental Example 5) to a more remarkable extent than in the other examples.

This suggest that piezoelectric members including a BLFM layer in contact with the substrate (electrode) are likely to be oriented preferentially in the <100> direction as a whole, and that as the BT layer is disposed closer to the BLFM layer, the piezoelectric member is more likely to be oriented preferentially in the <100> direction.

FIG. 9 shows the XRD patterns of the piezoelectric members of Experimental Examples 9 to 11. The XRD patterns of Referential Example 3 and Comparative Example 3 show the same results as those of the above Referential Examples and Comparative Examples.

From the results of Experimental Examples 9 and 10, it has been found that structures fired in a state where BT layers are disposed on a BLFM layer have a random crystal orientation. Also, from the results of Experimental Example 11, it has been found that firing in a state where a BLFM layer has been formed as the first layer allows the BT layers to have extremely good preferred orientation in the <100> direction. Thus, it has been found that the effect of the BLFM layer on the crystal orientation can be enhanced by firing the BLFM layer as a seed layer before firing the BT layer.

The embodiments described above and modifications of the embodiments can be appropriately combined one with another. A combined embodiment can produce the effect of each embodiment and a synergistic effect.

The invention is not limited to the above-described embodiments, and various modifications may be made. For example, the invention includes substantially the same structure as the disclosed embodiment, for example, a structure including the same method and producing the same result or a method having the same intent and producing the same effect. Some elements unessential to the structure of the disclosed embodiment may be replaced. The structure of an embodiment of the invention includes an element producing the same effect or achieving the same object, as the structure of the disclosed embodiment. The structures of the disclosed embodiments may be combined with a known art.

What is claimed is:

1. A piezoelectric element comprising:
electrodes; and
a piezoelectric member which is disposed between the electrodes,
wherein the piezoelectric member includes:
a first layer containing bismuth and titanium; and
a second layer containing bismuth lanthanum iron and manganese.

2. The piezoelectric element according to claim 1,
wherein the first layer mainly contains bismuth titanate and the second layer mainly containing bismuth lanthanum ferrate manganate.

3. The piezoelectric element according to claim 1, wherein the second layer adjoins at least one of the electrodes.

4. The piezoelectric element according to claim 1, wherein the second layer is disposed between the first layers.

5. The piezoelectric element according to claim 1, wherein the total thickness of the first layer is equal to or larger than the total thickness of the second layer.

6. A liquid ejecting head comprising the piezoelectric element as set forth in claim 1.

7. A liquid ejecting apparatus comprising the liquid ejecting head as set forth in claim 5.
